(19) United States
(12) Patent Application Publication
(10) Pub. No.: US 2026/0081121 A1
(43) Pub. Date: Mar. 19, 2026

(54) PLASMA PROCESSING SYSTEM AND EXHAUST SYSTEM

(71) Applicant: EBARA CORPORATION, Tokyo (JP)

(72) Inventors: Fumiya OKAZAKI, Tokyo (JP); Kohtaro KAWAMURA, Tokyo (JP); Hiroya SASAKI, Tokyo (JP)

(21) Appl. No.: 19/310,008

(22) Filed: Aug. 26, 2025

(30) Foreign Application Priority Data
Sep. 13, 2024 (JP) 2024-158935

(51) Int. Cl. H01J 37/32

(52) U.S. Cl. CPC H01J 37/32844; H01J 37/32449; H01J 2237/334

(57) ABSTRACT

A plasma processing system including a filter device capable of removing particles in gas without using liquid, including: a plasma generator configured to perform plasma processing and oxidation processing on a process gas to form a powder; and a trap device for removing the powder from gas containing the powder. The trap device includes: a chamber; an inlet pipe configured to cause the plasma generator to be in fluid communication with the chamber, the inlet pipe having an inlet opening located inside or on a surface of the chamber; and an outlet pipe for exhausting gas in the chamber to outside of the chamber, the outlet pipe having an outlet opening located inside or on a surface of the chamber, the chamber does not contain any liquid and is in a dry state, and the inlet opening and the outlet opening are not placed to face each other.

### CROSS-REFERENCE TO RELATED APPLICATION

This application is based upon and claims benefits of priorities from Japanese Patent Application No. 2024-158935 filed on Sep. 13, 2024, the entire contents of which are incorporated herein by reference.

### TECHNICAL FIELD

The present invention relates to a plasma processing system and an exhaust system.

### BACKGROUND ART

Plasma processing systems are used to abate exhaust gases exhausted from semiconductor processing devices. A known example of such a plasma processing system is a semiconductor waste abatement system disclosed in PTL 1.

A semiconductor waste abatement system 10 of PTL 1 includes a vacuum pump 18 for evacuating a semiconductor chamber, an abatement device 12, and a filter device 16 as shown in FIG. 1 of PTL 1. The abatement device 12 is configured to abate the exhaust gas flowing from a semiconductor processing chamber 14, and to supply the abated exhaust gas to the filter device 16. The filter device 16 is configured to remove particles produced when exhaust gas is abated, from the exhaust gas. More specifically, the filter device 16 has a filter chamber 118 as shown in FIG. 6 of PTL 1. The filter chamber 118 forms a liquid reservoir 120 for holding a filter liquid that filters the particles from the process gas flowing into the filter device 16. As a result, when the exhaust gas supplied from the abatement device 12 flows through the filter chamber 118, the particles contained in the exhaust gas are separated from the gas flow and adsorbed to the filter liquid.

### CITATION LIST

### Patent Literature

PTL 1: Japanese Translation of PCT International Application Publication No. 2023-542946

PTL 2: Japanese Patent Laid-Open No. 2023-59416

### SUMMARY OF INVENTION

### Technical Problem

The filter device 16 disclosed in PTL 1 is assumed to be used under an extremely low pressure obtained by evacuation with the vacuum pump 18. Therefore, a filter liquid with a low vapor pressure needs to be used in the filter device 16. If a filter liquid with a high vapor pressure is used, the filter liquid will vaporize and increase the pressure in the vacuum. However, a filter liquid with a low vapor pressure is expensive and increases the running costs of the device.

Furthermore, in order to use the filter liquid for a relatively long period of time, the filter liquid is circulated within the device while being filtered by a filter, and thereby the filter liquid can be saved. In such a case, however, a filter and a liquid circulation device are required. As a result, the cost of the device may increase, and the footprint of the entire device may be larger due to the placement of the filter and the liquid circulation device. This requires a filter device that can remove particles in gas without using liquid.

In view of the above, an object of the present disclosure is to provide a plasma processing system and an exhaust system including a filter device capable of removing particles in gas without using liquid.

### Solution to Problem

A plasma processing system according to the present disclosure includes: a plasma generator, in fluid communication with a semiconductor chamber of a semiconductor manufacturing device, configured to perform plasma processing and oxidation processing on a process gas and form a powder, the process gas being supplied from the semiconductor chamber; and a trap device, in fluid communication with the plasma generator, for removing the powder from gas containing the powder, wherein the trap device includes: a chamber; an inlet pipe configured to cause the plasma generator to be in fluid communication with the chamber, the inlet pipe having an inlet opening located inside the chamber or on a surface of the chamber; and an outlet pipe for exhausting gas in the chamber to an outside of the chamber, the outlet pipe having an outlet opening located inside the chamber or on a surface of the chamber, the chamber does not contain any liquid and is in a dry state, and the inlet opening and the outlet opening are not placed to face each other.

An exhaust system according to the present disclosure includes: the plasma processing system described above; the semiconductor manufacturing device including the semiconductor chamber; a vacuum pump for evacuating the semiconductor chamber via the plasma generator and the trap device; and an abatement device for receiving gas exhausted from the vacuum pump and for rendering the gas, having been received, harmless.

A plasma processing system according to the present disclosure includes: a plasma generator, in fluid communication with a semiconductor chamber of a semiconductor manufacturing device, configured to perform plasma processing and oxidation processing on a process gas to powder the gas and form a powder, the process gas being supplied from the semiconductor chamber; and a trap device, in fluid communication with the plasma generator, for removing the powder from gas containing the powder, wherein the trap device includes: a chamber; an inlet pipe configured to cause the plasma generator to be in fluid communication with the chamber, the inlet pipe having an inlet opening located inside the chamber or on a surface of the chamber; an outlet pipe for exhausting gas in the chamber to an outside of the chamber, the outlet pipe having an outlet opening located inside the chamber or on a surface of the chamber; and a shield located between the inlet opening and the outlet opening, and the chamber does not contain any liquid and is in a dry state.

### BRIEF DESCRIPTION OF DRAWINGS

FIG. 1 is a block diagram of an exhaust system according to an embodiment of the present disclosure;

FIG. 2 is a structural diagram showing a configuration of a plasma generator shown in FIG. 1;

FIG. 3A is a structural diagram showing a configuration of a trap device shown in FIG. 1;

FIG. 3B is a cross-sectional view of the trap device shown in FIG. 3A;

FIG. 4A is a cross-sectional view showing an example in which an inlet opening and an outlet opening are placed to face each other;

FIG. 4B is a cross-sectional view showing an example in which an inlet opening and an outlet opening are placed to face each other;

FIG. 5A is a structural diagram showing a configuration of a trap device that is different from the trap device in FIG. 3A;

FIG. 5B is a cross-sectional view of the trap device shown in FIG. 5A;

FIG. 6A is a structural diagram showing a configuration of a trap device that is different from the trap device in FIG. 3A;

FIG. 6B is a plan view of the trap device shown in FIG. 6A;

FIG. 6C is a cross-sectional view of the trap device shown in FIG. 6A;

FIG. 7 is a cross-sectional view showing a configuration of a trap device that is different from the trap device of FIG. 3A;

FIG. 8 is a perspective view of a plasma processing system according to another embodiment of the present disclosure;

FIG. 9 is a block diagram of a plasma processing system according to still another embodiment of the present disclosure;

FIG. 10 is a block diagram of an exhaust system according to still another embodiment of the present disclosure; and

FIG. 11 is a block diagram of an exhaust system according to still another embodiment of the present disclosure.

### DESCRIPTION OF EMBODIMENTS

Embodiments of the present invention are described below with reference to the drawings. In the drawings described below, identical or corresponding components are given the same reference numerals and duplicated description is omitted.

### <<Exhaust System 100>>

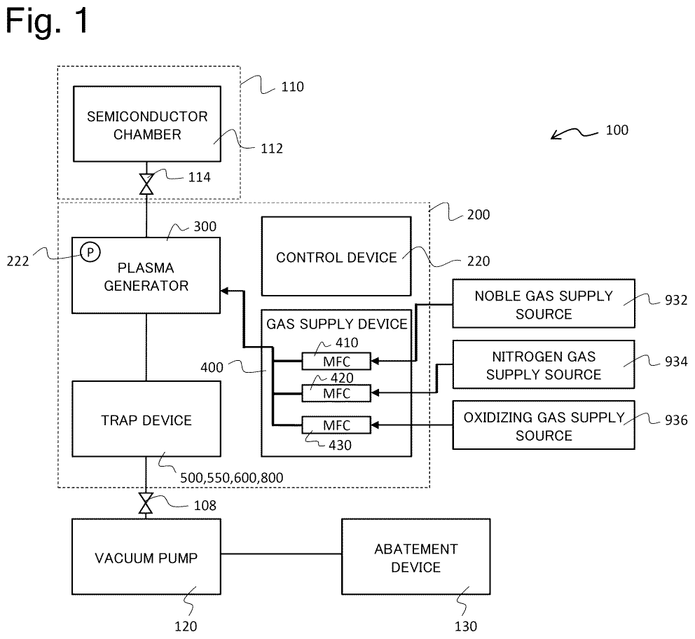

FIG. 1 is a block diagram of an exhaust system 100 according to an embodiment of the present disclosure. With reference to FIG. 1, the exhaust system 100 includes, for example, a plasma processing system 200, a semiconductor manufacturing device 110, a vacuum pump 120, and an abatement device 130. First, each component of the exhaust system 100 will be described.

### <<Semiconductor Manufacturing Device 110>>

The semiconductor manufacturing device 110 includes, for example, a semiconductor chamber 112 and a valve 114. The semiconductor manufacturing device 110 is, for example, a device for providing a process gas to a substrate placed in a semiconductor chamber 112 and performing a film formation process on the substrate. The semiconductor chamber 112 is connected to a plasma generator 300 of the plasma processing system 200. Therefore, the process gas after being used in the film formation process is exhausted to the plasma generator 300. The valve 114 also has a function of adjusting the flow rate of the process gas exhausted from the semiconductor chamber 112. Note that the semiconductor manufacturing device herein means a device that performs some kind of processing on a substrate in semiconductor manufacturing. For example, the semiconductor manufacturing device may include a chemical vapor deposition (CVD) device or an atomic layer deposition (ALD) device. The semiconductor manufacturing device may also be, for example, a device for manufacturing flat panel displays (FPDs) or solar cells.

### <<Vacuum Pump 120>>

The vacuum pump 120 is in fluid communication with the semiconductor chamber 112 via the plasma generator 300 and a trap device 500 of the plasma processing system 200. The vacuum pump 120 is used to suck in the process gas inside the semiconductor chamber 112 and create a vacuum inside the semiconductor chamber 112. For example, the vacuum pump 120 is configured to make the pressure on the suction port side from 10 Pa to 1333 Pa during suction. The vacuum pump 120 is also connected to the abatement device 130. Therefore, the gas sucked from the semiconductor chamber 112 by the vacuum pump 120 flows to the abatement device 130.

### <<Abatement Device 130>>

The abatement device 130 has a function of rendering the process gas harmless by a known method. Process gases to be used in semiconductor manufacturing may contain harmful flammable gases such as silane gas (SiH₄), dichlorosilane gas (SiH₂Cl₂), and ammonia (NH₃). Furthermore, there are harmful flammable liquid sources, such as tetraethyl orthosilicate (Si(OC₂H₅)₄), which are liquid at room temperature and are vaporized, by being vaporized or sprayed into a mist, to be used. When such a harmful flammable liquid source is used, the process gas may contain halogen-based persistent gases such as HF, F₂, Cl₂, NF₃, ClF₃, SF₆, CHF₃, C₂F₆ and CF₄, and/or gases such as H₂, O₂, O₃ and noble gases. For this reason, the process gas exhausted by the vacuum pump 120 cannot be released directly into the atmosphere, but is rendered harmless by the abatement device 130. The process gas after being rendered harmless is released into the atmosphere through an exhaust system including an exhaust pipe.

### <<Plasma Processing System 200>>

Depending on the specifications of the semiconductor manufacturing device 110, the process gas may contain metal components such as Zr, Hf, Ti, La, Mo, Ru, and Co. When such metal components react with the oxidation source, metal oxide powder is formed. If the powder gets caught in the gaps between the rotors of the vacuum pump 120 or in the gaps between the rotors and the casing that houses the rotors, the powder may hinder the normal rotation of the vacuum pump 120. For this reason, the exhaust system 100 includes a plasma processing system 200 having a function of removing metal components from the process gas between the semiconductor chamber 112 and the vacuum pump 120 in order to protect the vacuum pump 120. The detailed configuration of the plasma processing system 200 is described below.

The plasma processing system 200 includes, for example, the plasma generator 300, the trap device 500, a gas supply device 400, and a control device 220, as shown in FIG. 1.

### <Gas Supply Device 400>

The gas supply device 400 is connected to a noble gas supply source 932, a nitrogen gas supply source 934, and an oxidizing gas supply source 936. The nitrogen gas supply source 934 is configured to supply nitrogen gas to the gas supply device 400. The noble gas supply source 932 is configured to supply a noble gas to the gas supply device 400. The oxidizing gas supply source 936 is configured to supply an oxidizing gas to the gas supply device 400. Note that the oxidizing gas may be any gas that can supply oxygen in an oxidation reaction, and may be, for example, O₂, O₃, N₂O, H₂O₂, ClOₓ, NOx, H₂O, H₂+O₂, halogen gas+O₂, or any combination thereof. This causes a noble gas, nitrogen gas, and an oxidizing gas to be supplied to the gas supply device 400. The gas supply device 400 is connected to the plasma generator 300. The gas supply device 400 is configured to supply a noble gas, nitrogen gas, and an oxidizing gas to the plasma generator 300 at an appropriate flow rate. More specifically, the gas supply device 400 includes a first flow rate control device 410 for adjusting the flow rate of the noble gas, a second flow rate control device 420 for adjusting the flow rate of the nitrogen gas, and a third flow rate control device 430 for adjusting the flow rate of the oxidizing gas. The first flow rate control device 410, the second flow rate control device 420, and the third flow rate control device 430 are, for example, mass flow rate control devices.

### <Plasma Generator 300>

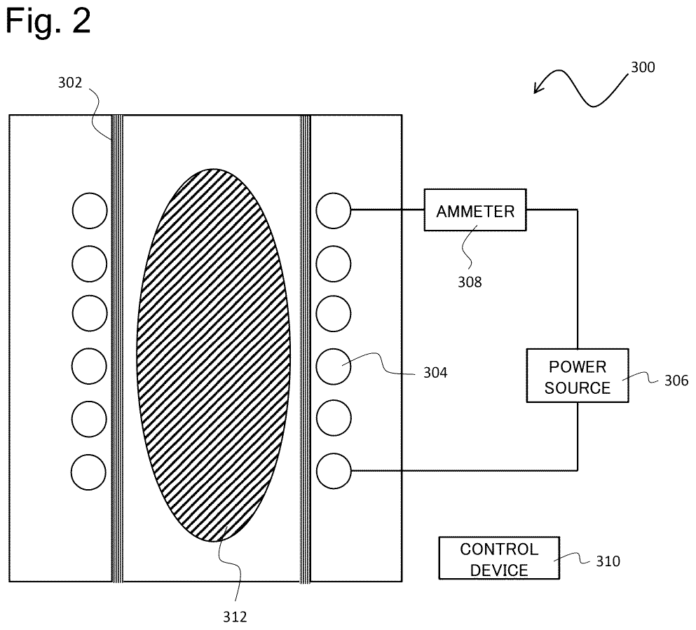

Next, refer to FIG. 2. FIG. 2 is a structural diagram showing the configuration of the plasma generator 300 shown in FIG. 1. With reference to FIG. 2, the plasma generator 300 includes a ceramic tube 302, a coil 304 wound around the outer circumference of the ceramic tube 302, and a power source 306. In the plasma generator 300, when a noble gas, nitrogen gas, and an oxidizing gas are supplied to the plasma generator 300, the power source 306 applies a current of a predetermined frequency to the coil 304, thereby generating a strong electromagnetic wave inside the ceramic tube 302 and generating plasma 312. Here, the coil 304 is made of copper (Cu), for example. The ceramic tube 302 is made of, for example, any one of aluminum nitride (AlN), alumina (Al₂O₃), zirconium oxide (ZrO₂), hafnium oxide (HfO₂), yttria (Y₂O₃), and quartz (SiO₂). In another embodiment of the present disclosure, the ceramic tube 302 to be used may be a high-temperature corrosion-resistant austenitic metal such as stainless steel, Hastelloy, or Inconel, with the above-described ceramic sprayed onto the surface. In still another embodiment of the present disclosure, the plasma generator 300 may generate the plasma 312 by other known methods.

As shown in FIG. 1, the plasma generator 300 is in fluid communication with the semiconductor chamber 112. Therefore, the plasma generator 300 is supplied with a process gas from the semiconductor chamber 112. The process gas may contain metal components. The plasma generator 300 performs plasma processing and oxidation processing on the process gas, thereby forming a powder of metal oxide (MeₓO_{y})^{R} from the metal components contained in the process gas, in which: Me indicates metal, and MeₓO_{y} is used as a general term for metal oxides; and R indicates a state in which electrons or the like have been added to metal oxides by plasma processing. In other words, the plasma generator 300 has a function of oxidizing and powdering metal components.

Furthermore, the plasma generator 300 has a function of rendering the process gas harmless. For example, when tris(dimethylamino)cyclopentadienyl zirconium (Zr[(C₅H₅)(N(CH₃)₂)]₃, hereinafter referred to as “ZAC”) is used as a precursor in the semiconductor manufacturing device 110, (CH₃)₂NH is produced as a by-product from ZAC during semiconductor manufacturing in the semiconductor chamber 112. (CH₃)₂NH is known to be explosive. The plasma generator 300 performs plasma processing and oxidation processing on (CH₃)₂NH, causing the following chemical reaction. As a result, (CH₃)₂NH is completely oxidized, loses its explosiveness, and is rendered harmless.

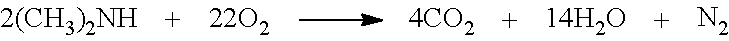

The plasma generator 300 therefore has a function of rendering harmful process gases, such as explosive, flammable, and toxic, harmless through an oxidation reaction.

In addition, depending on the specifications of the semiconductor manufacturing device 110, the flow rate of the process gas supplied to the plasma generator 300 may not be stable. This may fluctuate the flow rate of the process gas supplied to the plasma generator 300. This fluctuation in the flow rate of the process gas may cause the pressure inside the plasma generator 300 to fluctuate, preventing the plasma generator 300 from being able to generate stable plasma 312.

In contrast, the plasma processing system 200 has a pressure gauge 222 for measuring the pressure inside the plasma generator 300 (see FIG. 1). As described above, the gas supply device 400 has a first flow rate control device 410 for adjusting the flow rate of the noble gas, a second flow rate control device 420 for adjusting the flow rate of the nitrogen gas, and a third flow rate control device 430 for adjusting the flow rate of the oxidizing gas. The control device 220 is configured to control the first flow rate control device 410, the second flow rate control device 420, and the third flow rate control device 430 in accordance with the pressure measured by the pressure gauge 222. As a result, if the flow rate of the process gas supplied to the plasma generator 300 fluctuates, the control device 220 can change the flow rate of the noble gas, the flow rate of the oxidizing gas, and the flow rate of the nitrogen gas in accordance with the pressure fluctuation, allowing the plasma generator 300 to generate stable plasma.

With reference to FIG. 2, the plasma generator 300 further includes an ammeter 308 for measuring the current flowing through the coil 304, and a control device 310. The control device 310 is configured to execute at least one of the following first process and second process if the maximum value of the current measured by the ammeter 308 is larger than a predetermined value while the power source 306 applies a current to the coil 304. In the first process, the control device 310 increases the current to be applied by the power source 306 to the coil 304. On the other hand, in the second process, the control device 310 increases the frequency of the current to be applied to the coil 304.

When the plasma generator 300 generates the plasma 312, power is used to generate the plasma 312, and the current flowing through the coil 304 is reduced compared to when the plasma 312 is not generated. Therefore, if the maximum value of the current measured by the ammeter 308 is larger than a predetermined value, plasma 312 is presumably not being generated.

On the other hand, it is known that plasma 312 is more likely to be generated when the current applied to coil 304 increases or when the frequency of the current applied to coil 304 increases. Therefore, when the plasma 312 is presumably not being generated, the control device 310 attempts to reignite the plasma 312 under conditions that make the plasma 312 more likely to be generated. In other words, the plasma generator 300 has a function of reigniting the plasma 312.

### <Trap Device 500>

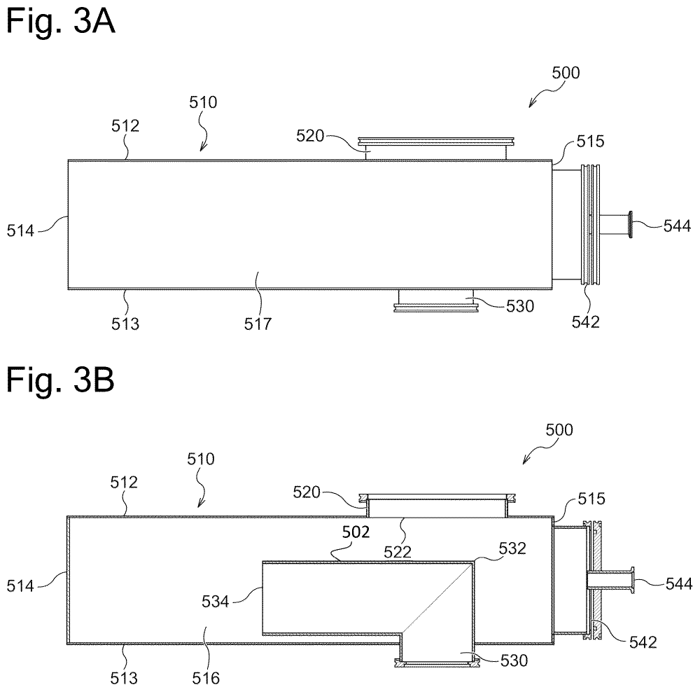

FIG. 3A is a structural diagram showing the configuration of the trap device 500 shown in FIG. 1. FIG. 3B is a cross-sectional view of trap device 500. The trap device 500 is in fluid communication with the plasma generator 300 and has a function of removing powder from the powder-containing gas supplied from the plasma generator 300 (see FIG. 1). More specifically, the trap device 500 has, for example, a chamber 510, an inlet pipe 520, and an outlet pipe 530. The chamber 510 has a rectangular parallelepiped shape, for example, and has an upper surface 512, a bottom surface 513, and four side surfaces 514, 515, 516, 517 connecting the upper surface 512 and the bottom surface 513. The upper surface 512, the bottom surface 513, and the side surfaces 514, 515, 516, 517 are thin rectangular plates. Note that the upper surface 512, the bottom surface 513, and the side surfaces 514, 515, 516, 517 are surfaces of the chamber 510. The chamber 510 does not contain any liquid and is in a dry state. Note that the chamber 510 may have a shape such as a sphere or a cylinder.

The inlet pipe 520 is configured to be in fluid communication with the plasma generator 300 and the chamber 510. The inlet pipe 520 has an inlet opening 522 located on the upper surface 512. In other words, the inlet opening 522 faces the bottom surface 513. Note that in the present disclosure, the “direction of the opening of the pipe” means the direction from inside the pipe through the opening to the outside of the pipe.

On the other hand, the outlet pipe 530 is configured to exhaust the gas in the chamber 510 to the vacuum pump 120 outside the chamber 510. More specifically, the outlet pipe 530 penetrates the bottom surface 513, bends in an L-shape at a bend portion 532 located inside the chamber 510, and extends from bend portion 532 toward the side surface 514. The outlet pipe 530 has an outlet opening 534 located inside the chamber 510. The outlet opening 534 does not face upward, but faces toward the side surface 514. In other words, in the trap device 500, the inlet opening 522 and the outlet opening 534 are not placed to face each other. Then, the body of the outlet pipe 530 is located between the inlet opening 522 and the outlet opening 534, and the body of the outlet pipe 530 serves as a shield 502. In other words, the shield 502 is necessarily present on any straight line connecting the inlet opening 522 and the outlet opening 534, making it impossible to draw a straight line connecting the inlet opening 522 and the outlet opening 534 that does not pass through the shield 502.

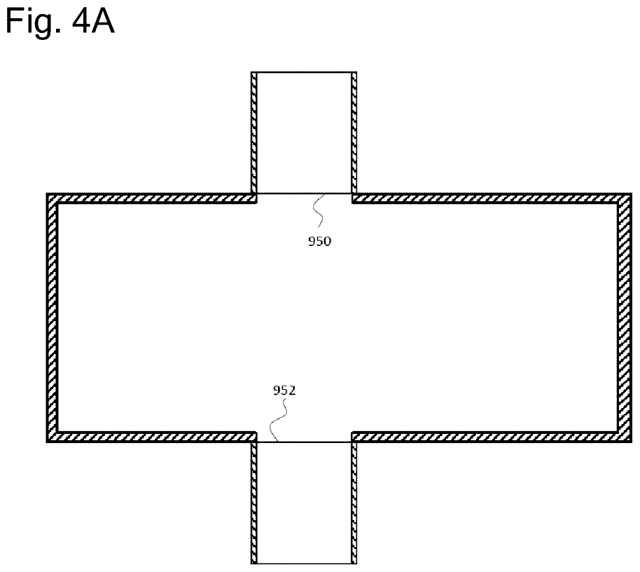

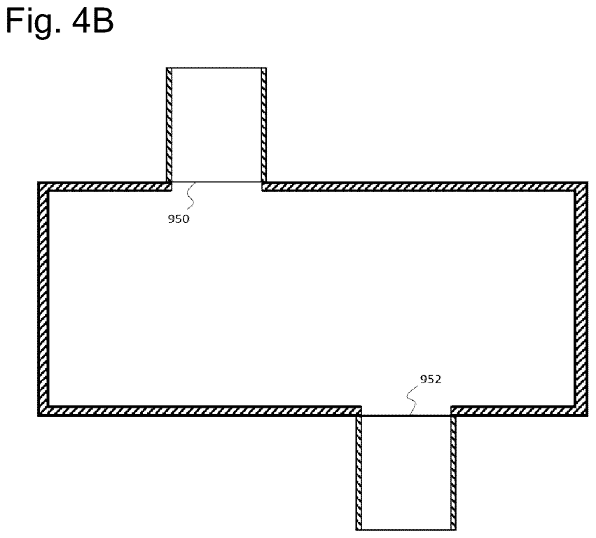

Note that in the present disclosure, “an aspect in which the inlet opening and the outlet opening are placed to face each other” means an aspect in which an outlet opening 952 is located in front of an inlet opening 950 as shown in FIG. 4A, as well as an aspect in which an inlet opening 950 and an outlet opening 952 are shifted in a parallel direction and face each other as shown in FIG. 4B. In other words, the aspect in which the inlet opening and the outlet opening are not placed to face each other does not include at least the aspects shown in FIG. 4A and FIG. 4B.

As described above, in trap device 500, the inlet opening 522 and the outlet opening 534 are not placed to face each other. Therefore, the gas having flowed in from the inlet opening 522 cannot move linearly toward the outlet opening 534. In other words, the gas having flowed in from the inlet opening 522 wanders inside the chamber 510 toward the outlet opening 534. As a result, the pressure loss of the gas flowing in the chamber 510 increases. Furthermore, the chamber 510 is relatively larger than the inlet pipe 520. Therefore, the gas can flow through a relatively larger space when it flows inside the chamber 510 than when it flows through the inlet pipe 520. In other words, the gas can flow through a flow path having a relatively larger cross-sectional area when it flows inside the chamber 510 than when it flows through the inlet pipe 520. As a result, the gas flow velocity is slower inside the chamber 510. When the gas flow velocity slows down, the particles contained in the gas are less likely to be stirred up by the gas flow, and are deposited on the bottom surface 513 of the chamber 510 and removed. In other words, the trap device 500 can remove particles contained in the gas.

Here, there are preferably more regions inside the chamber 510 where the flow velocity of the upward component of the gas is slower than the settling velocity of the particles. This is because in such regions, particles that have fallen once will not be stirred upward by the gas. For example, the trap device 500 may be configured so that 50%, 60%, 70%, 80%, or 90% or more of the total volume inside the chamber 510 is in such regions.

The trap device 500 is not limited to the above configuration as long as the aspect is such that the inlet opening 522 and the outlet opening 534 are not placed to face each other. In another embodiment of the present disclosure, for example, the inlet opening 522 may be located inside the chamber 510, and the outlet opening 534 may be located on the surface of the chamber 510.

The trap device 500 also includes, for example, a powder collection port 542 and a service port 544. The powder collection port 542 is disposed on the side surface 515, for example. The powder collection port 542 is used to collect the powder deposited inside the chamber 510. The service port 544 is disposed on the side surface 515, for example. The service port 544 is used for attaching an analyzer.

### <Trap Device 550>

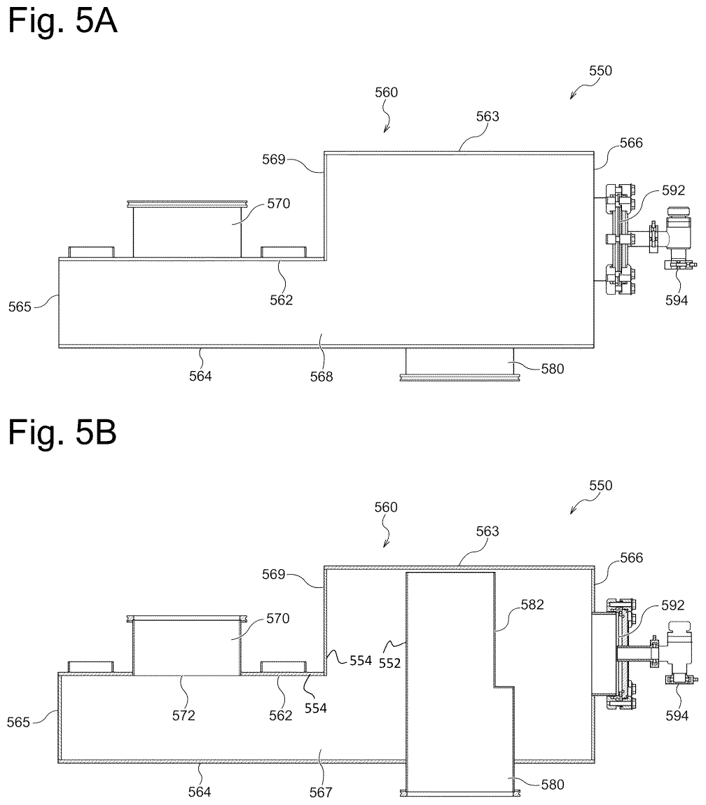

FIG. 5A is a structural diagram showing the configuration of a trap device 550 that is different from the trap device 500. FIG. 5B is a cross-sectional view of the trap device 550. The trap device 550 is replaceable with the trap device 500 in the exhaust system 100 and is configured to be usable in the exhaust system 100.

The trap device 550 is in fluid communication with the plasma generator 300 and has a function of removing powder from the powder-containing gas supplied from the plasma generator 300 (see FIG. 1). More specifically, the trap device 550 includes, for example, a chamber 560, an inlet pipe 570, and an outlet pipe 580. The chamber 560 has an L-shaped cross section and has a first upper surface 562, a second upper surface 563, a bottom surface 564, and five side surfaces 565, 566, 567, 567, 568, 569. Note that the first upper surface 562, the second upper surface 563, the bottom surface 564, and the five side surfaces 565, 566, 567, 567, 568, 569 are surfaces of chamber 560. The first upper surface 562, the second upper surface 563, and the bottom surface 564 are thin rectangular plates. The second upper surface 563 is located higher than the first upper surface 562. The side surfaces 565, 566, 569 are thin rectangular plates. The side surface 565 connects the first upper surface 562 and the bottom surface 564. The side surface 566 connects the second upper surface 563 and the bottom surface 564. The side surface 569 connects the first upper surface 562 and the second upper surface 563. The side surfaces 567, 568 are L-shaped thin plates. The side surfaces 567, 568 connect the first upper surface 562, the second upper surface 563, and the bottom surface 564. The chamber 560 does not contain any liquid and is in a dry state.

The inlet pipe 570 is configured to cause the plasma generator 300 to be in fluid communication with the chamber 560 (see FIG. 1). The inlet pipe 570 has an inlet opening 572 located on the first upper surface 562. In other words, the inlet opening 572 faces the bottom surface 564.

On the other hand, the outlet pipe 580 is configured to exhaust the gas in the chamber 560 to the vacuum pump 120 outside the chamber 560. More specifically, the outlet pipe 580 penetrates the bottom surface 564 at a portion located directly below the second upper surface 563, and extends inside the chamber 510 toward the second upper surface 563. The outlet pipe 580 has an outlet opening 582 located inside the chamber 560. The outlet opening 582 is formed in a portion where the outer circumferential surface of the outlet pipe 580 is cut out. The outlet opening 582 does not face upward, but faces toward the side surface 566. In other words, in the trap device 550, the inlet opening 572 and the outlet opening 582 are not placed to face each other. The body of the outlet pipe 580 and the wall surface of the chamber 560 are located between the inlet opening 572 and the outlet opening 584, and the body of the outlet pipe 580 and the wall surface of the chamber 560 serve as the shields 552, 554. In other words, the shields 552, 554 are necessarily present on any straight line connecting the inlet opening 572 and the outlet opening 582, making it impossible to draw a straight line connecting the inlet opening 572 and the outlet opening 582 that does not pass through the shields 552, 554.

As described above, in trap device 550, the inlet opening 572 and the outlet opening 582 are not placed to face each other. The trap device 550 can therefore remove particles contained in the gas using the same principle as that of the trap device 500 described above.

The trap device 550 also includes, for example, a powder collection port 592 and a service port 594. The powder collection port 592 is disposed on the side surface 566, for example. The powder collection port 592 is used to collect the powder deposited inside the chamber 560. The service port 594 is disposed on the side surface 566, for example. The chamber 560 is used for mounting an analyzer.

### <Trap Device 600>

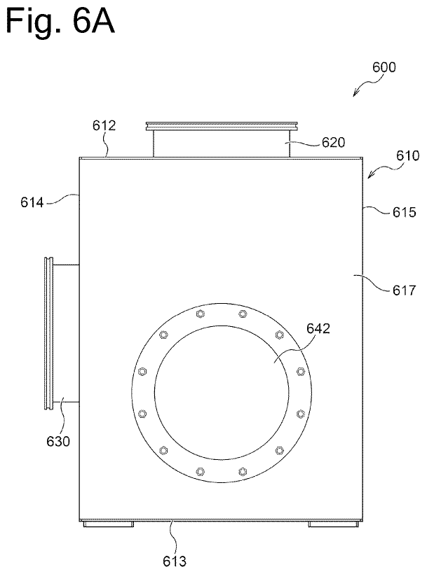

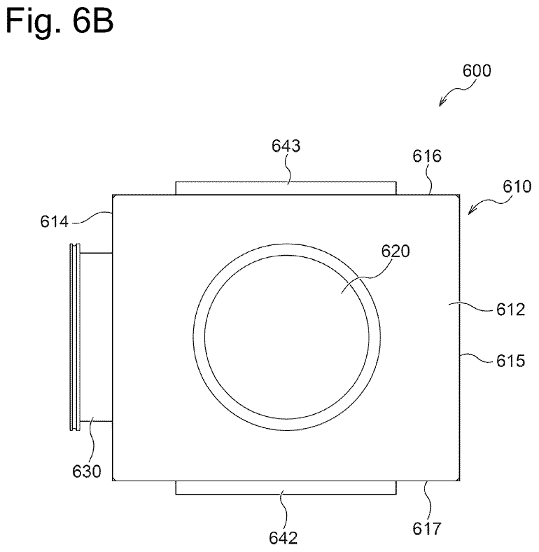

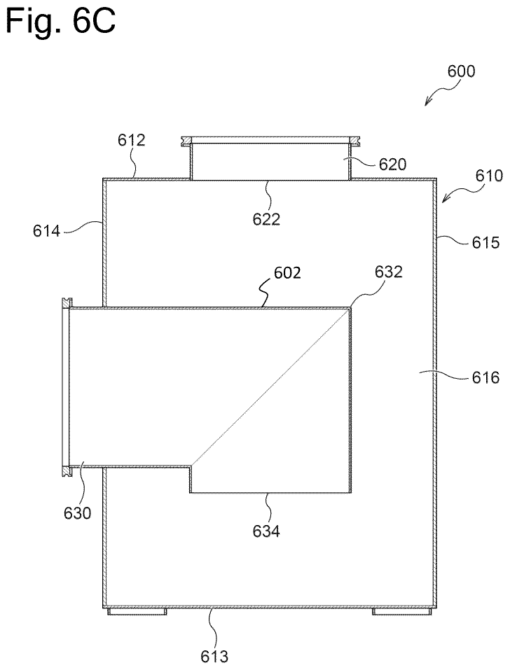

FIG. 6A is a structural diagram showing the configuration of a trap device 600 that is different from the trap devices 500 and 550. FIG. 6B is a plan view of the trap device 600. FIG. 6C is a cross-sectional view of the trap device 600. The trap device 600 is replaceable with the trap device 500 in the exhaust system 100 and is configured to be usable in the exhaust system 100.

The trap device 600 is in fluid communication with the plasma generator 300 and has a function of removing powder from the powder-containing gas supplied from the plasma generator 300 (see FIG. 1). More specifically, the trap device 600 includes, for example, a chamber 610, an inlet pipe 620, and an outlet pipe 630. The chamber 610 has a rectangular parallelepiped shape and has an upper surface 612, a bottom surface 613, and four side surfaces 614, 615, 616, 617 connecting the upper surface 612 and the bottom surface 613. The upper surface 612, the bottom surface 613, and the side surfaces 614, 615, 616, 617 are thin rectangular plates. Note that the upper surface 612, the bottom surface 613, and the side surfaces 614, 615, 616, 617 are surfaces of the chamber 610. The chamber 610 does not contain any liquid and is in a dry state.

The inlet pipe 620 is configured to cause the plasma generator 300 to be in fluid communication with the chamber 610 (see FIG. 1). The inlet pipe 620 has an inlet opening 622 located on the upper surface 612. In other words, the inlet opening 622 faces the bottom surface 613.

On the other hand, the outlet pipe 630 is configured to exhaust the gas in the chamber 610 to the vacuum pump 120 outside the chamber 610. More specifically, the outlet pipe 630 penetrates the side surface 614, bends in an L-shape at a bend portion 632 located inside the chamber 610, and extends from the bend portion 632 toward the bottom surface 613. The outlet pipe 630 has an outlet opening 634 located inside the chamber 610. The outlet opening 634 does not face upward, but faces toward the bottom surface 613. In other words, in the trap device 600, the inlet opening 622 and the outlet opening 634 are not placed to face each other. Then, the body of the outlet pipe 630 is located between the inlet opening 622 and the outlet opening 634, and the body of the outlet pipe 630 serves as the shield 602. In other words, the shield 602 is necessarily present on any straight line connecting the inlet opening 622 and the outlet opening 634, making it impossible to draw a straight line connecting the inlet opening 622 and the outlet opening 634 that does not pass through the shield 602.

As described above, in trap device 600, the inlet opening 622 and the outlet opening 634 are not placed to face each other. The trap device 600 can therefore remove particles contained in the gas using the same principle as that of the trap device 500 described above. The trap device 600 includes, for example, a powder collection ports 642, 643. The powder collection port 642 is disposed on the side surface 617, for example. The powder collection port 643 is disposed on the side surface 616, for example. The powder collection ports 642, 643 are used to collect the powder deposited inside the chamber 610. As described above, the trap device 600 may be provided with two or more powder collection ports 642, 643.

### <Trap Device 800>

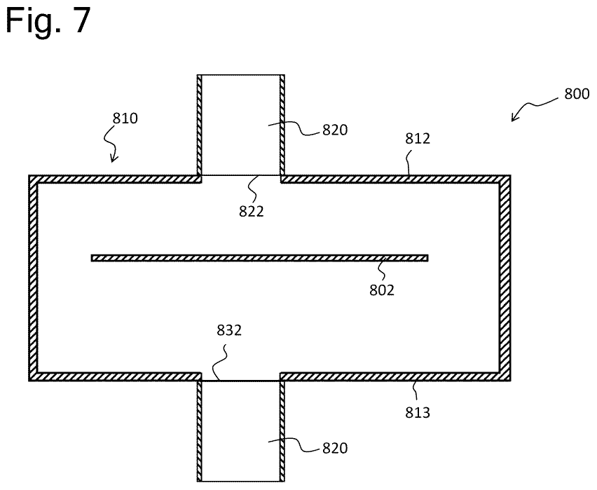

FIG. 7 is a cross-sectional view showing the configuration of a trap device 800 that is different from the trap device 500, trap device 550, and trap device 600. The trap device 800 is replaceable with the trap device 500 in the exhaust system 100 and is configured to be usable in the exhaust system 100.

The trap device 800 is in fluid communication with the plasma generator 300 and has a function of removing powder from the powder-containing gas supplied from the plasma generator 300 (see FIG. 1). More specifically, the trap device 800 includes, for example, a chamber 810, an inlet pipe 820, and an outlet pipe 830. The chamber 810 has a rectangular parallelepiped shape and has an upper surface 812, a bottom surface 813, and four side surfaces connecting the upper surface 812 and the bottom surface 813. The upper surface 812, the bottom surface 813, and the four side surfaces are thin rectangular plates. Note that the upper surface 812, the bottom surface 813, and the four side surfaces are surfaces of the chamber 810. The chamber 810 does not contain any liquid and is in a dry state.

The inlet pipe 820 is configured to cause the plasma generator 300 to be in fluid communication with the chamber 810 (see FIG. 1). The inlet pipe 820 has an inlet opening 822 located on the upper surface 812. In other words, the inlet opening 822 faces the bottom surface 813.

On the other hand, the outlet pipe 830 is configured to exhaust the gas in the chamber 810 to the vacuum pump 120 outside the chamber 810. The outlet pipe 830 has an outlet opening 832 located on the lower surface 813. In other words, the outlet opening 832 faces the upper surface 812. The inlet opening 822 and the outlet opening 832 are, for example, circular. For example, the center line of the inlet opening 822 coincides with the center line of the outlet opening 832. In other words, in the trap device 800, the inlet opening 822 and the outlet opening 832 are placed to face each other.

Furthermore, the trap device 800 includes a shield 802 located between the inlet opening 822 and the outlet opening 832. In other words, the shield 802 is necessarily present on any straight line connecting the inlet opening 822 and the outlet opening 832, making it impossible to draw a straight line connecting the inlet opening 822 and the outlet opening 832 that does not pass through the shield 802. The shield 802 is formed of a thin plate, for example.

As described above, in the trap device 800, the shield 802 is disposed between the inlet opening 822 and the outlet opening 832. Therefore, the gas having flowed in from the inlet opening 822 cannot move linearly toward the outlet opening 832. In other words, the gas having flowed in from the inlet opening 822 wanders inside the chamber 810 toward the outlet opening 832. As a result, the pressure loss of the gas flowing in the chamber 810 increases. Furthermore, the chamber 810 is relatively larger than the inlet pipe 820. Therefore, the gas can flow through a relatively larger space when it flows inside the chamber 810 than when it flows through the inlet pipe 820. In other words, the gas can flow through a flow path having a relatively larger cross-sectional area when it flows inside the chamber 810 than when it flows through the inlet pipe 820. As a result, the gas flow velocity is slower inside the chamber 810. When the gas flow velocity slows down, the particles contained in the gas are less likely to be stirred up by the gas flow, and are deposited on the bottom surface 813 of the chamber 810 and removed. In other words, the trap device 800 can remove particles contained in the gas.

If the vacuum pump 120 in the exhaust system 100 breaks down and stops, the vacuum pressure of the plasma generator 300 is not secured (see FIG. 1). In this case, the plasma generator 300 can increase the power applied to the coil 304 by the power source 306, thereby maintaining the generation of plasma. However, increase in power applies a high load to each device of the plasma generator 300, which is not preferable. In addition, if abatement device 130 breaks down and stops, gas that has not been abated is released into the atmosphere, which is not preferable.

In contrast, in the exhaust system 100, when the control device 220 detects the stop of any of the plasma generator 300, the vacuum pump 120, and the abatement device 130, the control device 220 stops the remaining devices among the plasma generator 300, vacuum pump 120, and abatement device 130 and outputs a signal to the semiconductor manufacturing device 110 to stop the semiconductor manufacturing process. This prevents the adverse effect of releasing harmful gases when any of the plasma generator 300, vacuum pump 120, and abatement device 130 stops.

In addition, the exhaust system 100 includes a valve 108. The valve 108 has a function of adjusting the flow rate of gas supplied from the trap device 500 to the vacuum pump 120.

In addition, when some malfunction occurs in the plasma processing system 200 or when maintenance is performed to remove the collected powder from inside the trap device 500, the worker sometimes wants to disconnect the plasma processing system 200 from the semiconductor manufacturing device 110 and the vacuum pump 120. If the semiconductor chamber 112 is opened to the atmospheric pressure when the worker disconnects the plasma processing system 200 from the semiconductor manufacturing device 110, more steps are required when the semiconductor manufacturing device 110 resumes operation. As a result, the time until operation is resumed is lengthened. In contrast, in the exhaust system 100, the worker can disconnect the plasma processing system 200 from the semiconductor manufacturing device 110 with the valve 114 closed. As a result, the semiconductor chamber 112 is not opened to the atmospheric pressure, and the time until operation resumes is shortened. Note that the worker may close the valve 108 together with the valve 114 when disconnecting the plasma processing system 200 from the semiconductor manufacturing device 110. This is because the adverse effects are prevented that are caused by the vacuum pump 120 being opened to the atmospheric pressure, which is described below.

If the vacuum pump 120 is opened to the atmospheric pressure when the worker disconnects the plasma processing system 200 from the vacuum pump 120, the air pressure inside the vacuum pump 120 increases, and a longer time is required until the vacuum pump 120 restarts creating a vacuum state. In contrast, in exhaust system 100, the worker can disconnect plasma processing system 200 from vacuum pump 180 with valve 108 closed. This prevents the vacuum pump 120 from being opened to the atmospheric pressure, and shortens the time until the vacuum pump 120 restarts creating a vacuum state. Note that the worker may close valve 114 together with valve 108 when disconnecting plasma processing system 200 from vacuum pump 120. This is because the above-described adverse effects are prevented that are caused by the semiconductor chamber 112 being opened to the atmospheric pressure.

### <<Plasma Processing System 202>>

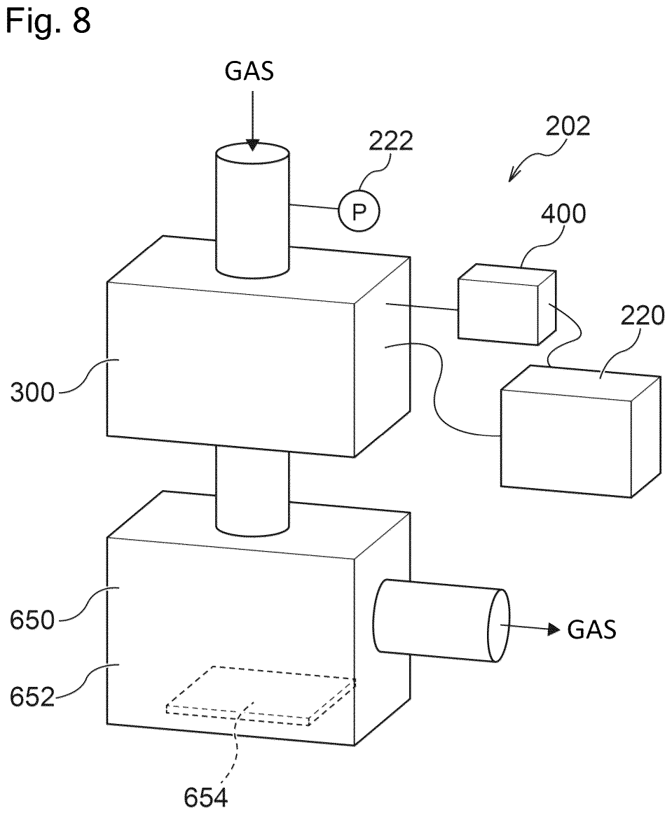

FIG. 8 is a perspective view of a plasma processing system 202 according to another embodiment of the present disclosure. The plasma processing system 202 is replaceable with the plasma processing system 200 in the exhaust system 100, and is configured to be usable in the exhaust system 100. With reference to FIG. 8, the plasma processing system 202 includes, for example, a plasma generator 300, a trap device 650, a gas supply device 400, and a control device 220. The plasma generator 300, the gas supply device 400, and the control device 220 of the plasma processing system 202 have, for example, the same configuration as those of the plasma processing system 200. For this reason, the description of these is omitted.

The trap device 650 includes, for example, a chamber 652 and a powder collector 654. The powder collector 654 is disposed in the chamber 652 and configured to be positively charged. More specifically, the powder collector 654 is a conductive plate and is connected to a power source (not shown). The powder collector 654 is positively charged when a voltage is applied from a power source.

As described above, the powder contained in the gas discharged from plasma generator 300 is metal oxide (MeₓO_{y})^{R}. When exposed to the plasma 312, the metal oxide (MeₓO_{y})^{R} collides with ions and electrons and to be negatively charged. When such negatively charged metal oxide (MeₓO_{y})^{R} powder enters the inside of the trap device 650, it is attracted to the powder collector 654 by Coulomb force. As a result, the trap device 650 can collect a larger amount of powder than when the trap device 650 does not have the powder collector 654.

Note that in another embodiment of the present disclosure, the above-described trap devices 500, 550, 600, 800 each may include a powder collector 654.

### <<Plasma Processing System 204>>

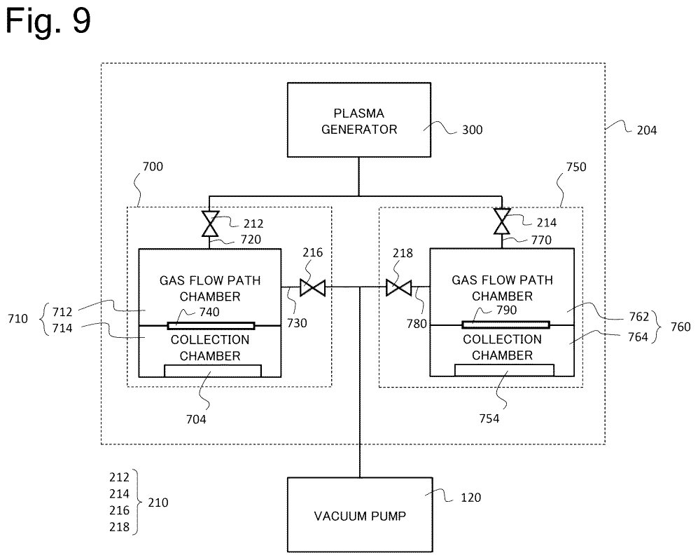

FIG. 9 is a block diagram of a plasma processing system 204 according to still another embodiment of the present disclosure. The plasma processing system 204 is replaceable with the plasma processing system 200 in the exhaust system 100, and is configured to be usable in the exhaust system 100. With reference to FIG. 9, the plasma processing system 204 includes, for example, a plasma generator 300, a trap device (an example of a first trap device) 700, a trap device (an example of a second trap device) 750, and a switching device 210. The plasma generator 300 of the plasma processing system 202 has the same configuration as that of the plasma processing system 200, for example. For this reason, the description of plasma generator 300 is omitted.

With reference to FIG. 9, the trap device 700 is in fluid communication with the plasma generator 300 and has a function of removing powder from the powder-containing gas supplied from the plasma generator 300. More specifically, the trap device 700 includes, for example, a chamber 710, an inlet pipe 720, an outlet pipe 730, a shutter 740, and a powder collector 704. The chamber 710 does not contain any liquid and is in a dry state. The chamber 710 further includes a gas flow path chamber 712 and a collection chamber 714.

The powder collector 704 is located inside the collection chamber 714 and is configured to be positively charged. Therefore, the powder collected by the trap device 700 is attracted to the powder collector 704 and a larger amount of the powder deposits inside the collection chamber 714.

The shutter 740 is, for example, a gate valve that can be closed to separate the gas flow path chamber 712 and the collection chamber 714. The trap device 700 is configured such that when the shutter 740 is closed, the inlet pipe 720 is in fluid communication with the outlet pipe 730 via the gas flow path chamber 712, not via the collection chamber 714. Therefore, closure of the shutter 740 allows the collection chamber 714 to be opened to the atmosphere while maintaining the vacuum pressure of the gas flow path chamber 712. In other words, if the shutter 740 is closed, the worker can access the collection chamber 714 with the exhaust system 100 kept in operation, and can collect the powder accumulated in the collection chamber 714.

On the other hand, the trap device 750 is in fluid communication with the plasma generator 300 and has a function of removing powder from the powder-containing gas supplied from the plasma generator 300. More specifically, the trap device 750 includes, for example, a chamber 760, an inlet pipe 770, an outlet pipe 780, a shutter 790, and a powder collector 754. The chamber 760 does not contain any liquid and is in a dry state. The chamber 760 further includes a gas flow path chamber 762 and a collection chamber 764.

The powder collector 754 is located inside the collection chamber 764 and is configured to be positively charged. Therefore, the powder collected by the trap device 750 is attracted to the powder collector 754 and a larger amount of the powder deposits inside the collection chamber 764.

The shutter 790 is, for example, a gate valve that can be closed to separate the gas flow path chamber 762 and the collection chamber 764. The trap device 750 is configured such that when the shutter 790 is closed, the inlet pipe 770 is in fluid communication with the outlet pipe 780 via the gas flow path chamber 762, not via the collection chamber 764. Therefore, closure of the shutter 790 allows the collection chamber 764 to be opened to the atmosphere while maintaining the vacuum pressure of the gas flow path chamber 762. In other words, if the shutter 790 is closed, the worker can access the collection chamber 764 with the exhaust system 100 kept in operation, and can collect the powder accumulated in the collection chamber 764.

The switching device 210 contains powder supplied from the plasma generator 300. More specifically, the switching device 210 includes a valve 212, a valve 214, a valve 216, and a valve 218. The valve 212 is attached to the inlet pipe 720 and has a function of adjusting the flow rate of the gas flowing through the inlet pipe 720. The valve 214 is attached to the outlet pipe 730 and has a function of adjusting the flow rate of the gas flowing through the outlet pipe 730. The valve 216 is attached to the inlet pipe 770 and has a function of adjusting the flow rate of the gas flowing through the inlet pipe 770. The valve 218 is attached to the outlet pipe 780 and has a function of adjusting the flow rate of the gas flowing through the outlet pipe 780.

In the plasma processing system 204, the valves 212 and 216 are opened, and thereby the gas supplied from the plasma generator 300 is supplied to the trap device 700. On the other hand, the valves 214 and 218 are opened, and thereby the gas supplied from the plasma generator 300 is supplied to the trap device 750. In other words, when either the trap device 700 or the trap device 750 is in maintenance, the plasma processing system 204 can also remove particles in the gas by using the other trap device 700, 750. In other words, in the plasma processing system 204, the worker can perform maintenance on either of the trap devices 700, 750 without stopping operation.

As described above, the plasma processing system 204 includes two trap devices 700, 750, but is not limited to this configuration. In another embodiment of the present disclosure, for example, the plasma processing system 204 may include three or more trap devices and a switching device configured to switch the supply destinations of the gas among these trap devices.

### <<Exhaust System 102>>

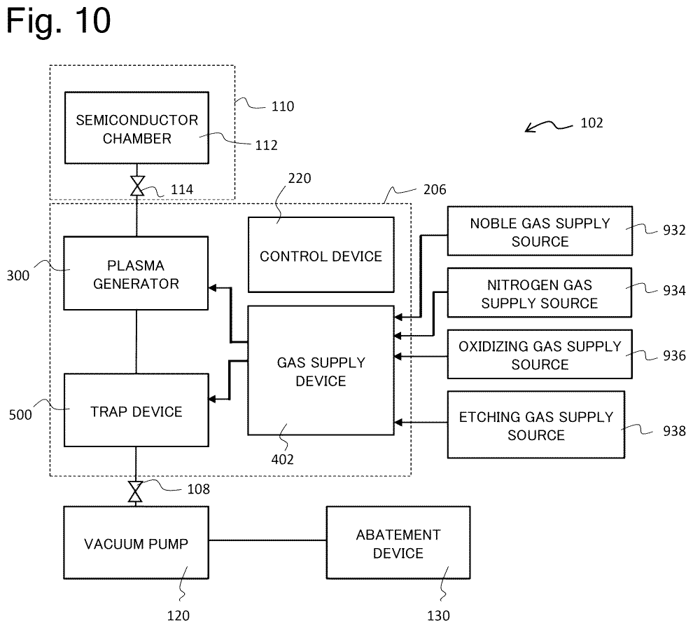

FIG. 10 is a block diagram of an exhaust system 102 that is different from the exhaust system 100. With reference to FIG. 10, the exhaust system 102 includes, for example, a plasma processing system 206, a semiconductor manufacturing device 110, a vacuum pump 120, and an abatement device 130. The semiconductor manufacturing device 110, vacuum pump 120, and abatement device 130 of exhaust system 102 have, for example, the same configuration as those of exhaust system 100. For this reason, the description of these is omitted. The plasma processing system 206 includes, for example, a plasma generator 300, a trap device 500, a gas supply device 402, and a control device 220. The plasma generator 300, the trap device 500, and the control device 220 of the plasma processing system 206 have, for example, the same configuration as those of the plasma processing system 200. For this reason, the description of these is omitted.

With reference to FIG. 10, the gas supply device 402 is connected to an etching gas supply source 983. The etching gas supply source 983 is configured to supply an etching gas to the gas supply device 400. In addition, the gas supply device 402 is connected to the trap device 500. The gas supply device 402 is configured to supply the etching gas to the trap device 500 at an appropriate flow rate. More specifically, the gas supply device 402 has a flow rate control device (not shown) for adjusting the flow rate of the etching gas. When the etching gas is supplied to the trap device 500, the etching gas reacts with the powder deposited in the trap device 500 and can vaporize the powder. As a result, the vaporized powder passes through the vacuum pump 120 and the abatement device 130 and is discharged to the outside of the device. In other words, the plasma processing system 206 can remove the powder deposited in the trap device 500 using the etching gas, and thereby reduces the speed at which powder is deposited on the trap device 500. As a result, the plasma processing system 206 can reduce the frequency of work for collecting powder from the trap device 500. Note that the etching gas is selected according to the physical properties of the powder to be deposited. For example, the etching gas may include NF₃, CF₄, ClF₃, C₄F₈, C₂F₆, SF₆, and/or H₂.

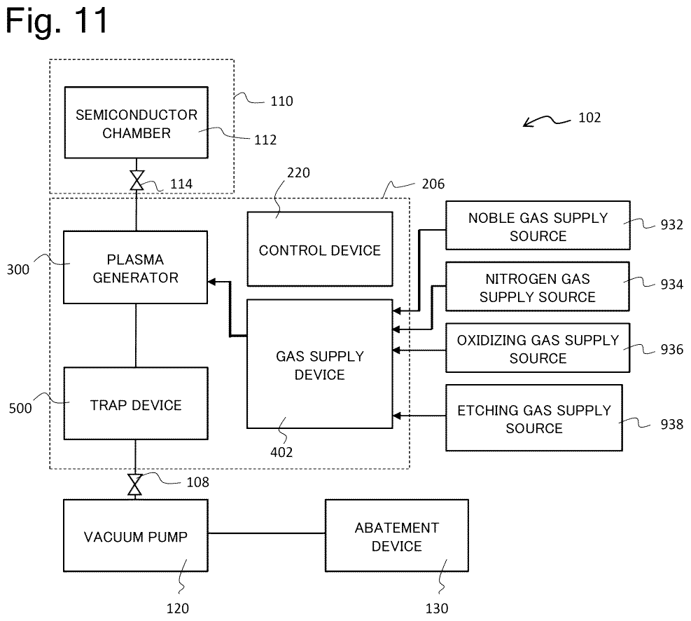

In another embodiment of the present disclosure, as shown in FIG. 11, the gas supply device 402 may be configured to supply the etching gas to the plasma generator 300 instead of supplying it to the trap device 500. In this case, the plasma generator 300 can radicalize the etching gas supplied from the gas supply device 402 and supply the radicalized etching gas to the trap device 500. As a result, the plasma processing system 206 can remove the powder deposited in the trap device 500 in the same manner as in FIG. 10, and can reduce the frequency of work for collecting powder from the trap device 500.

### [Supplementary Notes]

Some or all of the above embodiments may be described as the following supplementary notes, but are not limited to the following.

### (Supplementary Note 1)

The plasma processing system according to Supplementary Note 1 includes: a plasma generator, in fluid communication with a semiconductor chamber of a semiconductor manufacturing device, configured to perform plasma processing and oxidation processing on a process gas to powder the gas and form a powder, the process gas being supplied from the semiconductor chamber; and a trap device, in fluid communication with the plasma generator, for removing the powder from gas containing the powder, wherein the trap device includes: a chamber; an inlet pipe configured to cause the plasma generator to be in fluid communication with the chamber, the inlet pipe having an inlet opening located inside the chamber or on a surface of the chamber; and an outlet pipe for exhausting gas in the chamber to an outside of the chamber, the outlet pipe having an outlet opening located inside the chamber or on a surface of the chamber, the chamber does not contain any liquid and is in a dry state, and the inlet opening and the outlet opening are not placed to face each other.

### (Supplementary Note 2)

The plasma processing system according to Supplementary Note 2 is the plasma processing system according to Supplementary Note 1, wherein the trap device includes a powder collector within the chamber, the powder collector being configured to be positively charged.

### (Supplementary Note 3)

The plasma processing system according to Supplementary Note 3 is the plasma processing system according to any one of Supplementary Notes 1 to 3, wherein the chamber has a rectangular parallelepiped shape and has an upper surface, a bottom surface, and side surfaces connecting the upper surface and the bottom surface, the inlet opening is located on the upper surface, and the outlet pipe penetrates the bottom surface, bends in an L-shape at a bend portion located inside the chamber, and extends from the bend portion toward at least one of the side surfaces.

### (Supplementary Note 4)

The plasma processing system according to Supplementary Note 4 is the plasma processing system according to any one of Supplementary Notes 1 to 3, wherein the chamber has an L-shaped cross section, and has a first upper surface, a second upper surface located higher than the first upper surface, and a bottom surface, the inlet opening is located on the first upper surface, the outlet pipe penetrates the bottom surface at a portion located directly below the second upper surface and extends inside the chamber toward the second upper surface, and the outlet opening is formed in a portion where an outer circumferential surface of the outlet pipe is cut out.

### (Supplementary Note 5)

The plasma processing system according to Supplementary Note 5 is the plasma processing system according to any one of Supplementary Notes 1 to 3, wherein the chamber has a rectangular parallelepiped shape and has an upper surface, a bottom surface, and side surfaces connecting the upper surface and the bottom surface, the inlet opening is located on the upper surface, and the outlet pipe penetrates at least one of the side surfaces, bends in an L-shape at a bend portion located inside the chamber, and extends from the bend portion toward the bottom surface.

### (Supplementary Note 6)

The plasma processing system according to Supplementary Note 6 is the plasma processing system according to Supplementary Note 2, wherein the chamber includes a gas flow path chamber and a collection chamber, the trap device includes a shutter that is closed to separate the gas flow path chamber and the collection chamber, when the shutter is closed, the inlet pipe is in fluid communication with the outlet pipe via the gas flow path chamber, and the powder collector is located inside the collection chamber.

### (Supplementary Note 7)

The plasma processing system according to Supplementary Note 7 is the plasma processing system according to any one of Supplementary Notes 1 to 6, including a gas supply device configured to supply an etching gas to the plasma generator, wherein the plasma generator is configured to radicalize the etching gas supplied from the gas supply device and to supply the etching gas, radicalized for removing the powder, to the trap device.

### (Supplementary Note 8)

The plasma processing system according to Supplementary Note 8 is the plasma processing system according to any one of Supplementary Notes 1 to 7, including a gas supply device configured to supply an etching gas, for removing the powder, to the trap device.

### (Supplementary Note 9)

The plasma processing system according to Supplementary Note 9 is the plasma processing system according to any one of Supplementary Notes 1 to 8, wherein the trap device is a first trap device, the plasma processing system includes: a second trap device, in fluid communication with the plasma generator, for removing the powder from gas containing the powder; and a switching device that switches supply destinations of gas between the first trap device and the second trap device, the gas being supplied from the plasma generator and containing the powder.

### (Supplementary Note 10)

The plasma processing system according to Supplementary Note 10 is the plasma processing system according to any one of Supplementary Notes 1 to 9, further including: a gas supply device for supplying a noble gas, nitrogen gas, and an oxidizing gas to the plasma generator; a pressure gauge for measuring pressure inside the plasma generator; and a control device, wherein the gas supply device includes: a first flow rate control device for adjusting a flow rate of the noble gas; a second flow rate control device for adjusting a flow rate of the nitrogen gas; and a third flow rate control device for adjusting a flow rate of the oxidizing gas, and the control device is configured to control the first flow rate control device, the second flow rate control device, and the third flow rate control device in accordance with a pressure measured by the pressure gauge.

### (Supplementary Note 11)

The exhaust system according to Supplementary Note 11 includes: the plasma processing system according to any one of Supplementary Notes 1 to 10; the semiconductor manufacturing device including the semiconductor chamber; a vacuum pump for evacuating the semiconductor chamber via the plasma generator and the trap device; and an abatement device for receiving gas exhausted from the vacuum pump and for rendering the gas, having been received, harmless.

### (Supplementary Note 12)

The exhaust system according to Supplementary Note 12 is the exhaust system according to Supplementary Note 11, including a control device, wherein when the control device detects stop of any device among the plasma generator, the vacuum pump, and the abatement device, the control device stops remaining devices among the plasma generator, the vacuum pump, and the abatement device, and outputs a signal to the semiconductor manufacturing device to stop a semiconductor manufacturing process.

### (Supplementary Note 13)

The plasma processing system according to Supplementary Note 13 is the plasma processing system according to any one of Supplementary Notes 1 to 10, wherein the plasma generator includes: a ceramic tube; a coil wound around an outer circumference of the ceramic tube; a power source that applies a current of a predetermined frequency to the coil; an ammeter for measuring current flowing through the coil; and a control device, the control device is configured to execute at least one of a first process and a second process when a maximum value of current measured by the ammeter is larger than a predetermined value while the power source applies a current to the coil, in the first process, the control device increases current to be applied by the power source to the coil, and in the second process, the control device increases frequency of current to be applied to the coil.

### (Supplementary Note 14)

The plasma processing system according to Supplementary Note 14 includes: a plasma generator, in fluid communication with a semiconductor chamber of a semiconductor manufacturing device, configured to perform plasma processing and oxidation processing on a process gas to powder the gas and form a powder, the process gas being supplied from the semiconductor chamber; and a trap device, in fluid communication with the plasma generator, for removing the powder from gas containing the powder, wherein the trap device includes: a chamber; an inlet pipe configured to cause the plasma generator to be in fluid communication with the chamber, the inlet pipe having an inlet opening located inside the chamber or on a surface of the chamber; an outlet pipe for exhausting gas in the chamber to an outside of the chamber, the outlet pipe having an outlet opening located inside the chamber or on a surface of the chamber; and a shield located between the inlet opening and the outlet opening, and the chamber does not contain any liquid and is in a dry state.

The above describes the embodiments of the present invention and each of the variations related thereto, but it goes without saying that the above-described examples are intended to facilitate understanding of the present invention and do not limit the present invention. The present invention can be modified and improved as appropriate without departing from the spirit of the invention, and equivalents thereof are included in the present invention. Furthermore, any combination or omission of each component described in the claims and specification is possible within the scope of solving at least part of the above-mentioned problems or achieving at least part of the effects.

### REFERENCE SIGNS LIST

100, 102: exhaust system
110: semiconductor manufacturing device
112: semiconductor chamber
120: vacuum pump
130: abatement device
200, 202, 204, 206: plasma processing system
210: switching device
220: control device
222: pressure gauge
300: plasma generator
302: ceramic tube
304: coil
306: power source
308: ammeter
310: control device
312: plasma
400, 402: gas supply device
410: first flow rate control device
420: second flow rate control device
430: third flow rate control device
500: trap device
510: chamber
520: inlet pipe
522: inlet opening
530: outlet pipe
532: bend portion
534: outlet opening
550: trap device
560: chamber
570: inlet pipe
572: inlet opening
580: outlet pipe
582: outlet opening
600: trap device
610: chamber
620: inlet pipe
622: inlet opening
630: outlet pipe
632: outlet opening
632: bend portion
634: outlet opening
642, 643: powder collection port
650: trap device
652: chamber
654: powder collector
700: trap device
704: powder collector
710: chamber
712: gas flow path chamber
714: collection chamber
720: inlet pipe
730: outlet pipe
740: shutter
750: trap device
754: powder collector
760: chamber
762: gas flow path chamber
764: collection chamber
770: inlet pipe
780: outlet pipe
790: shutter

What is claimed is:

1. A plasma processing system, comprising:
a plasma generator, in fluid communication with a semiconductor chamber of a semiconductor manufacturing device, configured to perform plasma processing and oxidation processing on a process gas to powder the gas and form a powder, the process gas being supplied from the semiconductor chamber; and
a trap device, in fluid communication with the plasma generator, for removing the powder from gas containing the powder, wherein
the trap device includes:
a chamber;
an inlet pipe configured to cause the plasma generator to be in fluid communication with the chamber, the inlet pipe having an inlet opening located inside the chamber or on a surface of the chamber; and
an outlet pipe for exhausting gas in the chamber to an outside of the chamber, the outlet pipe having an outlet opening located inside the chamber or on a surface of the chamber,
the chamber does not contain any liquid and is in a dry state, and
the inlet opening and the outlet opening are not placed to face each other.

2. The plasma processing system according to claim 1, wherein the trap device includes a powder collector within the chamber, the powder collector being configured to be positively charged.

3. The plasma processing system according to claim 1, wherein
the chamber has a rectangular parallelepiped shape and has an upper surface, a bottom surface, and side surfaces connecting the upper surface and the bottom surface,
the inlet opening is located on the upper surface, and
the outlet pipe penetrates the bottom surface, bends in an L-shape at a bend portion located inside the chamber, and extends from the bend portion toward at least one of the side surfaces.

4. The plasma processing system according to claim 1, wherein
the chamber has an L-shaped cross section, and has a first upper surface, a second upper surface located higher than the first upper surface, and a bottom surface,
the inlet opening is located on the first upper surface,
the outlet pipe penetrates the bottom surface at a portion located directly below the second upper surface and extends inside the chamber toward the second upper surface, and
the outlet opening is formed in a portion where an outer circumferential surface of the outlet pipe is cut out.

5. The plasma processing system according to claim 1, wherein
the chamber has a rectangular parallelepiped shape and has an upper surface, a bottom surface, and side surfaces connecting the upper surface and the bottom surface,
the inlet opening is located on the upper surface, and
the outlet pipe penetrates at least one of the side surfaces, bends in an L-shape at a bend portion located inside the chamber, and extends from the bend portion toward the bottom surface.

6. The plasma processing system according to claim 2, wherein
the chamber includes a gas flow path chamber and a collection chamber,
the trap device includes a shutter that is closed to separate the gas flow path chamber and the collection chamber,
when the shutter is closed, the inlet pipe is in fluid communication with the outlet pipe via the gas flow path chamber, and
the powder collector is located inside the collection chamber.

7. The plasma processing system according to claim 1, comprising a gas supply device configured to supply an etching gas to the plasma generator,
wherein the plasma generator is configured to radicalize the etching gas supplied from the gas supply device and to supply the etching gas, radicalized for removing the powder, to the trap device.

8. The plasma processing system according to claim 1, comprising a gas supply device configured to supply an etching gas, for removing the powder, to the trap device.

9. The plasma processing system according to claim 1, wherein
the trap device is a first trap device,
the plasma processing system includes:
a second trap device, in fluid communication with the plasma generator, for removing the powder from gas containing the powder; and
a switching device that switches supply destinations of gas between the first trap device and the second trap device, the gas being supplied from the plasma generator and containing the powder.

10. The plasma processing system according to claim 1, comprising:
a gas supply device for supplying a noble gas, nitrogen gas, and an oxidizing gas to the plasma generator;
a pressure gauge for measuring pressure inside the plasma generator; and
a control device,
wherein the gas supply device includes:
a first flow rate control device for adjusting a flow rate of the noble gas;
a second flow rate control device for adjusting a flow rate of the nitrogen gas; and
a third flow rate control device for adjusting a flow rate of the oxidizing gas, and
the control device is configured to control the first flow rate control device, the second flow rate control device, and the third flow rate control device in accordance with a pressure measured by the pressure gauge.

11. An exhaust system, comprising:
the plasma processing system according to claim 1;
the semiconductor manufacturing device including the semiconductor chamber;
a vacuum pump for evacuating the semiconductor chamber via the plasma generator and the trap device; and
an abatement device for receiving gas exhausted from the vacuum pump and for rendering the gas, having been received, harmless.

12. The exhaust system according to claim 11, comprising a control device,
wherein when the control device detects stop of any device among the plasma generator, the vacuum pump, and the abatement device, the control device stops remaining devices among the plasma generator, the vacuum pump, and the abatement device, and outputs a signal to the semiconductor manufacturing device to stop a semiconductor manufacturing process.

13. The plasma processing system according to claim 1, wherein
the plasma generator includes:
a ceramic tube;
a coil wound around an outer circumference of the ceramic tube;
a power source that applies a current of a predetermined frequency to the coil;
an ammeter for measuring current flowing through the coil; and
a control device,
the control device is configured to execute at least one of a first process and a second process when a maximum value of current measured by the ammeter is larger than a predetermined value while the power source applies a current to the coil,
in the first process, the control device increases current to be applied by the power source to the coil, and
in the second process, the control device increases frequency of current to be applied to the coil.

14. A plasma processing system, comprising:
a plasma generator, in fluid communication with a semiconductor chamber of a semiconductor manufacturing device, configured to perform plasma processing and oxidation processing on a process gas to powder the gas and form a powder, the process gas being supplied from the semiconductor chamber; and
a trap device, in fluid communication with the plasma generator, for removing the powder from gas containing the powder, wherein
the trap device includes:
a chamber;
an inlet pipe configured to cause the plasma generator to be in fluid communication with the chamber, the inlet pipe having an inlet opening located inside the chamber or on a surface of the chamber;
an outlet pipe for exhausting gas in the chamber to an outside of the chamber, the outlet pipe having an outlet opening located inside the chamber or on a surface of the chamber; and
a shield located between the inlet opening and the outlet opening, and
the chamber does not contain any liquid and is in a dry state.
